(19) United States
(12) Patent Application Publication
(10) Pub. No.: US 2017/0131910 A1
(43) Pub. Date: May 11, 2017

(54) REGISTER HAVING NON-VOLATILE MEMORY FOR BACKING UP AND RESTORING VOLATILE MEMORY

(71) Applicants: Commissariat à I'Énergie Atomique et aux Énergies Alternatives, Paris (FR); Centre National de la Recherche Scientifique, Paris Cedex 16 (FR)

(72) Inventors: Pierre Paoli, Grenoble (FR); Christophe Layer, Grenoble (FR); Virgile Javerliac, Grenoble (FR); Jean-Pierre Nozieres, Le Sappey En Chartreuse (FR)

(73) Assignees: Commissariat à I'Énergie Atomique et aux Énergies Alternatives, Paris (FR); Centre National de la Recherche Scientifique, Paris Cedex 16 (FR)

(21) Appl. No.: 15/319,453

(22) PCT Filed: Jun. 8, 2015
(86) PCT No.: PCT/FR2015/051509

§ 371 Date: Dec. 16, 2016

(30) Foreign Application Priority Data
Jun. 17, 2014 (FR) 1455558

(51) Int. Cl. G06F 3/06; G06F 13/42; G11C 13/00; G06F 13/40

(52) U.S. Cl. CPC G06F 3/065; G06F 3/0619; G06F 3/0685; G06F 13/4068; G06F 13/4282; G11C 13/0069; G11C 13/004

(57) ABSTRACT

A register including: a plurality of volatile memory cells each having a first input and an output, the volatile memory cells being coupled in series with each other via their first inputs and outputs; a non-volatile memory comprising a plurality of non-volatile memory cells; and one or more serial connections adapted to perform at least one of: serially supply data to be written to the non-volatile memory from a last or another of the volatile memory cells to the non-volatile memory during a back-up operation of data stored by the volatile memory cells; and serially supply data read from the non-volatile memory to a first of the volatile memory cells during a restoration operation of the data stored by the volatile memory cells.

### FIELD

The present disclosure relates to the field of registers, and in particular to a combined volatile and non-volatile register.

### BACKGROUND

It has been proposed to use programmable magnetoresistive elements in memory cells to provide non-volatile data storage. Such elements are programmable to adopt one of two different resistive states. The programmed resistive state is maintained even when a supply voltage of the memory cell is disconnected, and thus data can be stored by such elements in a non-volatile fashion.

Various types of magnetoresistive elements have been proposed, some of which are capable of being programmed by the direction of a current that is passed through the element. An example of such a current-programmable magnetoresistive element is a magnetic tunnel junction having a write mechanism based on STT (spin transfer torque).

Registers comprising a number of memory cells, such as D-type flip-flops, provide a means of storing data that can be accessed quickly, and with relatively low energy consumption.

However, there is a need in the art for a new type of memory register providing fast data access while also providing non-volatile data storage, and without significantly increasing surface area or energy consumption.

### SUMMARY

It is an aim of embodiments of the present description to at least partially address one or more needs in the prior art.

According to one aspect of the present disclosure, there is provided a register comprising: a plurality of volatile memory cells each having a first input and an output, the volatile memory cells being coupled in series with each other via their first inputs and outputs; a non-volatile memory comprising a plurality of non-volatile memory cells; and one or more serial connections, wherein the non-volatile memory comprises either: a common pair of write circuits for the plurality of non-volatile memory cells, and a read circuit associated with each of the non-volatile memory cells, each read circuit having its output coupled in parallel to a corresponding one of the volatile memory cells, the one or more serial connections being adapted to serially supply data to be written to the non-volatile memory from a last or another of the volatile memory cells to the non-volatile memory during a back-up operation of data stored by the volatile memory cells; or a common read circuit for the plurality of non-volatile memory cells, and a pair of write circuits associated with each of the non-volatile memory cells, each write circuit being controlled based on a corresponding one of the outputs of the volatile memory cells to program a data value in the corresponding non-volatile memory cell, the one or more serial connections being adapted to serially supply data read from the non-volatile memory to a first of the volatile memory cells during a restoration operation of the data stored by the volatile memory cells.

According to one aspect of the present disclosure, there is provided a register comprising: a plurality of volatile memory cells each having a first input and an output, the volatile memory cells being coupled in series with each other via their first inputs and outputs; a non-volatile memory comprising a plurality of non-volatile memory cells; and one or more serial connections adapted to perform at least one of: serially supply data to be written to the non-volatile memory from a last or another of the volatile memory cells to the non-volatile memory during a back-up operation of data stored by the volatile memory cells; and serially supply data read from the non-volatile memory to a first of the volatile memory cells during a restoration operation of the data stored by the volatile memory cells.

According to one embodiment, each of the volatile memory cells further comprises a second input for receiving data to be stored in the register, and a selection input for selecting one of the first and second inputs.

According to one embodiment, the register comprises a control block adapted to control the selection input of each of the volatile memory cells to select the first input during the restoration and/or back-up operation.

According to one embodiment, the one or more serial connections is further adapted to input scan test data in series to the first of the volatile memory cells during a scan test operation.

According to one embodiment, the register further comprises a feedback line coupling the output of the last of the volatile memory cells to the first input of the first of the volatile memory cells.

According to one embodiment, the outputs of the volatile memory cells are coupled in parallel to corresponding inputs of the non-volatile memory.

According to one embodiment, the non-volatile memory comprises: a common read circuit for the plurality of non-volatile memory cells; and a pair of write circuits associated with each of the non-volatile memory cells, each write circuit being controlled based on a corresponding one of the outputs of the volatile memory cells to program a data value in the corresponding non-volatile memory cell.

According to one embodiment, the non-volatile memory comprises: a common pair of write circuits for the plurality of non-volatile memory cells; and a read circuit associated with each of the non-volatile memory cells, each read circuit having its output coupled in parallel to a corresponding one of the volatile memory cells.

According to one embodiment, the one or more serial connections are adapted to supply the data read from the non-volatile memory in series to the first of the volatile memory cells during the restoration operation and to supply the data to be written to the non-volatile memory in series from the last or another of the volatile memory cells to the non-volatile memory during a back-up operation.

According to one embodiment, the non-volatile memory comprises: a common read circuit for the plurality of non-volatile memory cells; and a common pair of write circuits for the plurality of non-volatile memory cells.

According to one embodiment, each of the plurality of non-volatile memory cells comprises: first and second resistive elements, at least one of which is programmable to have one of at least two resistive states, a data value being represented by the relative resistances of the first and second resistive elements, the first resistive element being coupled between a first intermediate node and a first storage node of a read circuit and the second resistive element being coupled between a second intermediate node and a second storage node.

According to one embodiment, at least one of the first and second resistive elements is one of: a spin transfer torque element with in-plane anisotropy; a spin transfer torque element with perpendicular-to-plane anisotropy; a reduction oxide element; a ferro-electric element; and a phase change element.

According to a further aspect of the present disclosure, there is provided a method of data back-up in the above memory register, comprising: serially supplying, by the one or more serial connections, data to be written to the non-volatile memory from the last or another of the volatile memory cells.

According to a further aspect of the present disclosure, there is provided a method of restoring data in the above memory register, comprising: serially supplying, by the one or more serial connections, data read from the non-volatile memory to the first of the volatile memory cells.

### BRIEF DESCRIPTION OF THE DRAWINGS

The foregoing and other features and advantages will become apparent from the following detailed description of embodiments, given by way of illustration and not limitation with reference to the accompanying drawings, in which:

FIG. 1 schematically illustrates a register according to an example embodiment of the present disclosure;

FIG. 2 schematically illustrates a non-volatile memory of the register of FIG. 1 in more detail according to an example embodiment of the present disclosure;

FIG. 3 is a timing diagram showing examples of signals in the register of FIG. 1 and in the non-volatile memory of FIG. 2 during a back-up operation according to an example embodiment of the present disclosure;

FIG. 4 is a timing diagram showing examples of signals in the register of FIG. 1 and in the non-volatile memory of FIG. 2 during a restoration operation according to an example embodiment of the present disclosure;

FIG. 5 schematically illustrates the non-volatile memory of FIG. 1 in more detail according to a further example embodiment of the present disclosure;

FIG. 6 schematically illustrates the register of FIG. 1 in more detail according to a further example embodiment of the present disclosure; and

FIGS. 7A and 7B illustrate resistive elements based on magnetic tunnelling junctions according to example embodiments of the present disclosure.

### DETAILED DESCRIPTION

Throughout the following description, the term “connected” is used to refer to a direct connection between one element and another, while the term “coupled” implies that the connection between the two elements may be direct, or via an intermediate element, such as a transistor, resistor or other component.

FIG. 1 schematically illustrates a combined volatile/non-volatile register 100 according to an example embodiment. The register 100 comprises a volatile portion 102 comprising a plurality of volatile memory cells, and a non-volatile memory (NON-VOLATILE MEMORY) 103.

In the example of FIG. 1 the volatile portion 102 comprises four volatile memory cells 104 to 107, although in alternative embodiments it could comprise a different number, for example two or more. The volatile cells 104 to 107 are for example D-type flip-flops or other types of synchronous memory devices controlled by a clock signal CLK and each capable of storing one bit of data. The volatile cells are coupled in a series with each other to form a chain. For example, the volatile memory cells 104 to 107 comprise inputs S0 to S3 respectively and outputs Q0 to Q3 respectively, and they are coupled in series via these inputs and outputs. In particular, the output Q0 of the volatile cell 104 is for example coupled to the input S1 of the volatile cell 105, the output Q1 of the volatile cell 105 is coupled to the input S2 of the volatile cell 106, and so on and so forth. The output of the final volatile cell 107 in the chain is for example coupled via a feedback line 108 to the first volatile cell 104. The feedback line 108 is for example coupled to one input of a multiplexer 110, the output of the multiplexer 110 being coupled to the input S0 of the volatile cell 104.

The outputs Q0 to Q3 of the volatile cells 104 to 107 also for example provide corresponding data signals Q0 to Q3 to one or more other circuits (not illustrated in FIG. 1). The volatile cells for example further comprise inputs D0 to D3 respectively, for receiving corresponding data signals D0 to D3 to be stored in the memory register 100. The data signals D0 to D3 are for example provided by one or more other circuits (not illustrated in FIG. 1). Furthermore, each volatile cell 104 to 107 is for example controlled by a selection signal SE to select either the corresponding input S0 to S3 or the corresponding input D0 to D3.

The output Q3 of the volatile cell 107 is for example coupled to an input D_{V} of the non-volatile memory 103 via a line 112. The multiplexer 110 for example has another of its inputs coupled to an output D_{NV} of the non-volatile memory 103 via a line 114. The multiplexer 110 for example also has a third input coupled to an input line 115 for receiving a test data signal SCAN_IN. The multiplexer 110 is for example controlled by a signal M based on the mode of operation of the register 100, as will be described in more detail below. The control signals M and SE are for example provided by a control block (CTRL) 116.

The non-volatile memory 103 for example comprises a plurality of non-volatile memory cells (not illustrated in FIG. 1), each storing a bit of data in a non-volatile fashion. In some embodiments, the non-volatile memory cells comprise magnetoresistive elements. The non-volatile memory 103 for example comprises an input for receiving configuration data D_{CONFIG} allowing the non-volatile memory 103 to be programmed independently of the data stored in the volatile portion 102 of the register 100.

The register 100 is for example capable of operating in any of the following three main modes of operation: a test mode; a standard active mode; and a standby mode.

In the test mode, the control block 116 generates control signals SE and M that control the multiplexer 110 to select the scan test signal SCAN_IN and the volatile cells 104 to 107 to select the corresponding inputs S0 to S3. The scan test signal SCAN_IN is thus applied to the chain of volatile cells, and one of the output signals Q0 to Q3 is for example verified to ensure proper functioning of the register.

In the standard active mode, the register 100 is for example used to store the data signal D0 to D3 in a volatile fashion using the volatile memory cells 104 to 107. Thus, during the standard active mode, the control block 116 generates the control signal SE that controls the volatile cells 104 to 107 to select the corresponding inputs D0 to D3.

In the standby mode, the register 100 is for example powered down to conserve energy. Thus during the standby mode, the data stored by the volatile portion 102 of the register 100 is lost, and only the data stored by the non-volatile memory 103 is conserved. Periodically while the register 100 is in the standard active mode, and/or just before the register 100 enters the standby mode, a back-up operation is performed such that the data stored by the volatile cells 104 to 107 is stored in the non-volatile memory 103. Furthermore, when leaving the standby mode, a restoration operation is for example performed to reload the data from the non-volatile memory 103 to the volatile cells 104 to 107.

During the back-up and restoration operations, the control block 116 generates the control signal SE to control the volatile cells 104 to 107 to select the inputs S0 to S3 respectively, such that the volatile cells are coupled in series. At least one of the back-up and restoration operations is then performed serially, by transferring data serially between the volatile cells and the non-volatile memory of the register. For example, during a back-up operation, data is supplied serially via the serial connection provided by the line 112 from the volatile cell 107 to the non-volatile memory 103 of the register 100. Additionally or alternatively, during a restoration operation, data is inputted serially via the serial connection provided by the line 114 and the multiplexer 110, from the non-volatile memory 103 to the volatile cell 104.

It will be apparent to those skilled in the art that, rather than the line 112 being coupled to the output of the volatile cell 107, it could be coupled to the output of any of the other volatile cells. Furthermore, as represented by dashed arrows 117 in FIG. 1, in some embodiments the data at the outputs Q0 to Q3 of the volatile cells 104 to 107 are written to the non-volatile memory 103 in parallel during a back-up operation. An example of such an embodiment will be described below with reference to FIG. 5.

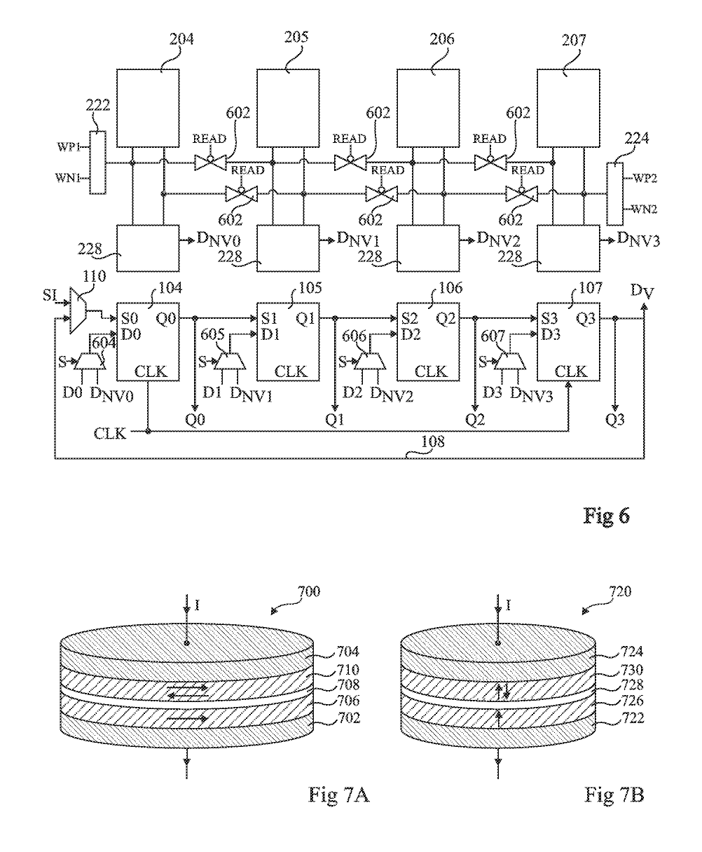

It will be equally apparent to those skilled in the art that, rather than the line 114 being coupled via the multiplexer 110 to an input of the volatile cell 104, it could be coupled to an input of any of the other volatile cells, for example via a corresponding multiplexer. Furthermore, as represented by dashed arrows 118 in FIG. 1, in some embodiments the data read from the non-volatile memory 103 could be provided in parallel to the volatile cells 104 to 107 during a restoration operation. An example of such an embodiment will be described below with reference to FIG. 6.

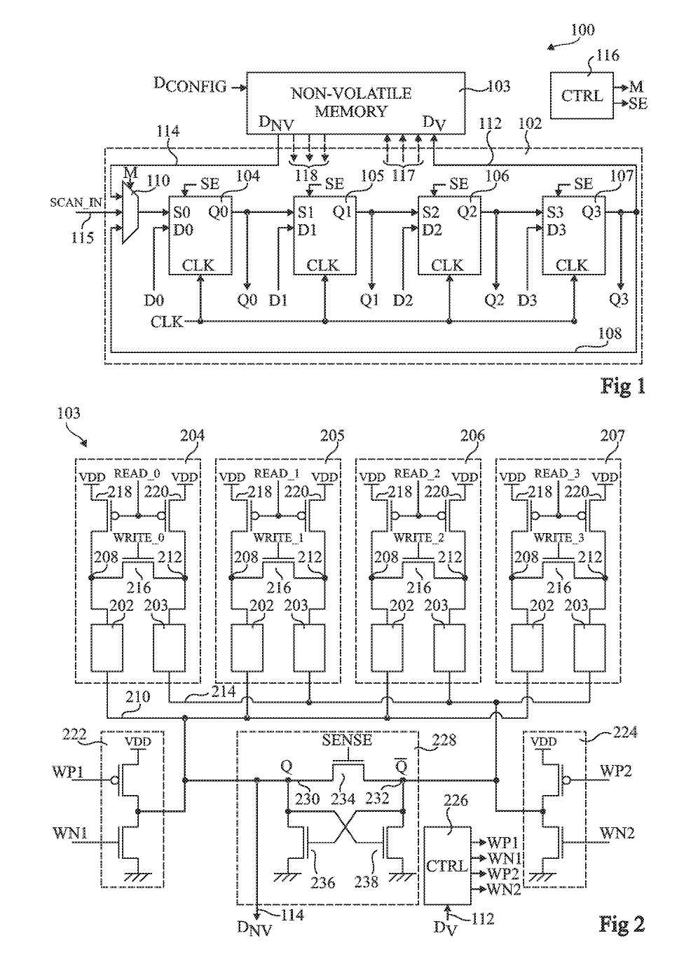

FIG. 2 schematically illustrates the non-volatile memory 103 in more detail according to an example embodiment in which data is both written to and read from the non-volatile memory 103 serially, uniquely via the lines 112 and 114.

The non-volatile memory 103 for example comprises a plurality of non-volatile memory cells each comprising a pair of programmable resistive elements 202, 203. In the example of FIG. 2 there are four non-volatile cells 204 to 207, but in alternative embodiments, there could be any number. In some embodiments, there are the same number of non-volatile cells as the number of volatile cells in the volatile portion 102 of the register 100.

Each of the resistive elements 202, 203 is capable of being programmed to have one of a plurality of resistive states. The resistive elements 202, 203 are any type of resistance switching element, such as magnetoresistive elements. In some embodiments, the elements 202, 203 are of the type having a resistance programmable by the direction of a current passed through them. As will be described in more detail below with reference to FIGS. 7A and 7B, the resistance switching elements 202, 203 are for example spin transfer torque elements with in-plane or perpendicular-to-plane anisotropy, as described in more detail in the publication entitled “Magnonic spin-transfer torque MRAM with low power, high speed, and error-free switching”, N.Mojumder et al., IEDM Tech. Digest (2010), and in the publication entitled “Electric toggling of magnets”, E. Tsymbal, Natural Materials Vol 11, January 2012. Alternatively, the resistive elements 202, 203 could be those used in RedOx RAM (reduction oxide RAM) resistive switching memories, which are for example described in more detail in the publication entitled “Redox-Based Resistive Switching Memories—Nanoionic Mechanisms, Prospects and Challenges”, Rainer Waser et al., Advanced Materials 2009, 21, pages 2632 to 2663. As yet a further example, the resistive elements could be those used in FeRAM (Ferro-Electric RAM) or in PCRAM (phase change RAM).

Whatever the type of resistive elements, a bit of data is for example stored in the non-volatile cells 204 to 207 in a non-volatile manner by setting one of the resistive elements at a relatively high resistance (Rₘₐₓ), and the other at a relatively low resistance (Rₘᵢₙ). Each of the resistive elements 202, 203 for example has just two resistive states corresponding to the high and low resistances Rₘₐₓ and Rₘᵢₙ, but the exact values of Rₘᵢₙ and Rₘₐₓ may vary depending on conditions such as process, materials, temperature variations etc.

The non-volatile data bit represented by the resistive elements 202, 203 depends on which of the resistive elements is at the resistance Rₘₐₓ and Rₘᵢₙ, in other words on the relative resistances. The resistive elements 202, 203 are for example selected such that the resistance Rₘₐₓ is always significantly greater than the resistance Rₘᵢₙ, for example at least 20 percent greater. In general, the ratio between the resistance Rₘₐₓ and the resistance Rₘᵢₙ is for example between 1.2 and 10000. The resistance Rₘᵢₙ is for example in the region of 2 k ohms or less, and the resistance Rₘₐₓ is for example in the region of 6 k ohms or more, although many other values are possible.

It will be apparent to those skilled in the art that in some embodiments, rather than both of the resistive elements 202, 203 being programmable, only one is programmable. In such a case, the other resistive element for example has a fixed resistance at an intermediate level around halfway between Rₘᵢₙ and Rₘₐₓ, for example equal, within a 10 percent tolerance, to (Rₘᵢₙ+(Rₘₐₓ−Rₘᵢₙ)/2). For example, one of the resistive elements 202, 203 could correspond to a resistor of fixed resistance. Alternatively, one of the resistive elements 202, 203 could be formed of a pair of programmable resistive elements coupled in parallel with each other and in opposite orientations, such irrespective of the sense in which each element is programmed, the resistance value remains relatively constant at the intermediate level.

The resistive element 202 in each non-volatile cell 204 to 207 is for example coupled between an intermediate node 208 and a common line 210 of the non-volatile cells. Similarly, the resistive element 203 is for example coupled between an intermediate node 212 and a common line 214 of the non-volatile cells. The intermediate nodes 208 and 212 are coupled together via the main current nodes of a transistor 216, which is for example an n-channel MOS (NMOS) transistor. The control nodes of the transistors 216 of the non-volatile cells 204 to 207 are for example controlled by corresponding write signals WRITE_0 to WRITE_3. The intermediate node 208 is for example further coupled to a supply voltage VDD via the main current nodes of a p-channel MOS (PMOS) transistor 218. Similarly, the node 212 is for example coupled to the supply voltage VDD via the main current nodes of a PMOS transistor 220. Control nodes of the PMOS transistors 218, 220 of the non-volatile cells 204 to 207 are for example controlled by corresponding read signals READ_0 to READ_3.

The non-volatile memory 103 for example comprises common write circuits 222 and 224. In particular, the common line 210 is for example coupled to the write circuit 222, and the common line 214 is for example coupled to the write circuit 224. The write circuit 222 is capable of coupling the common line 210 to ground or to the supply voltage VDD based on a pair of control signals WN1 and WP1. For example, the write circuit 222 comprises an NMOS transistor controlled by the signal WN1 and coupled by its main current nodes between the common line 210 and ground, and a PMOS transistor controlled by the signal WP1 and coupled by its main current nodes between the common line 210 and the supply voltage VDD. Similarly, the write circuit 224 is capable of coupling the common line 214 to ground or to the supply voltage VDD based on a pair of control signals WN2 and WP2. For example, the write circuit 222 comprises an NMOS transistor controlled by the signal WN2 and coupled by its main current nodes between the common line 214 and ground, and a PMOS transistor controlled by the signal WP2 and coupled by its main current nodes between the common line 214 and the supply voltage VDD.

The signals WP1, WN1, WP2 and WN2 are for example generated by a control block (CTRL) 226, based on the input data signal D_{V} received on line 112 from the volatile memory portion 102 of the register 100.

The non-volatile memory 103 also for example comprises a common read circuit 228 having a storage node 230 coupled to the common line 210, and a storage node 232 coupled to the common line 214. The storage nodes 230 and 232 are for example coupled together via the main current nodes of an NMOS transistor 234 controlled at its gate node by a signal SENSE. A pair of inverters is cross-coupled between the storage nodes 230 and 232. Each inverter is for example formed by a single transistor 236, 238 respectively. Transistor 236 is for example an NMOS transistor coupled by its main current nodes between node 230 and ground. Transistor 238 is for example an NMOS transistor coupled by its main current nodes between the storage node 232 and ground. A control node of transistor 236 is coupled to the storage node 232, and a control node of transistor 238 is coupled to the storage node 230. A high state of the voltage Q at the storage node 230 or of the voltage Q̅ at the storage node 232 is maintained by leakage current passing through the PMOS transistor 218 or 220 of each non-volatile cell 204 to 207. In particular, the threshold voltages of the PMOS transistors 218 and 220 are for example chosen to be lower than those of NMOS transistors 236 and 238, such that the leakage current through the transistors 218 and 220 when in the non-conductive state is higher than the leakage current through the transistor 236 or 238 when in the non-conductive state.

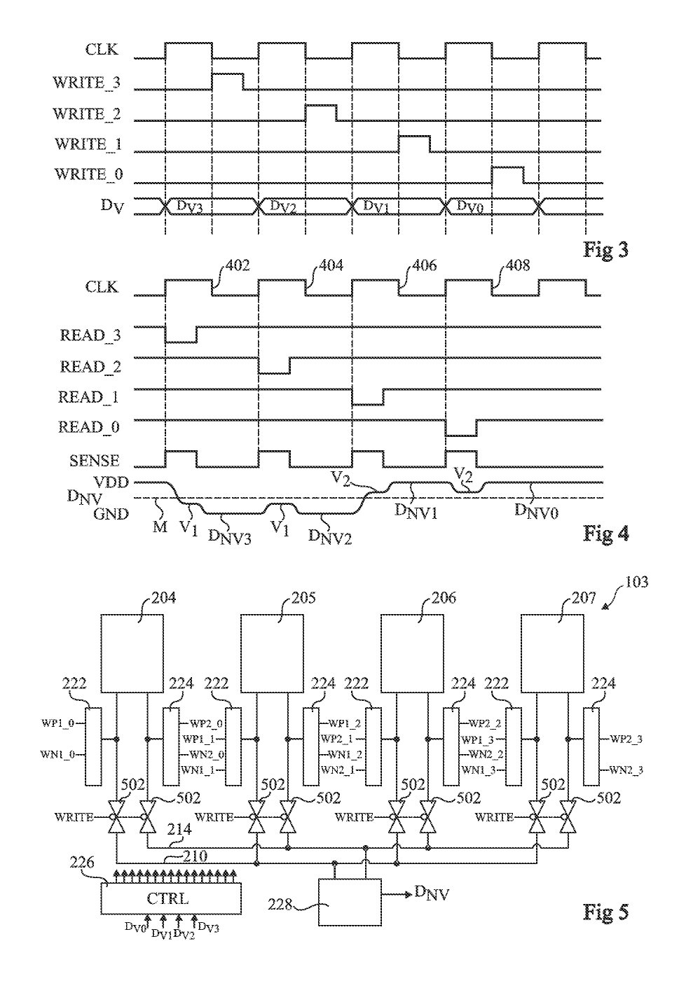

FIG. 3 is a timing diagram showing an example of signals in the register 100 of FIG. 1 and in the non-volatile memory of FIG. 2 during a back-up operation based on the data signal D_{V} from the volatile memory cells 104 to 107. In particular, FIG. 3 shows examples of the clock signal CLK, the write signals WRITE_3 to WRITE_0 controlling the transistors 216 of the non-volatile memory cells 207 to 204 respectively, and the data signal D_{V}.

During the back-up operation, the memory cells 104 to 107 are for example controlled by the selection signal SE to select the inputs S0 to S3 respectively to be propagated to their outputs. The data signal D_{V} for example transitions on rising edges of the clock signal CLK. Thus, calling the data values initially stored by the cells 104 to 107 at the start of the back-up phase D_{V0} to D_{V3} respectively, the data signal D_{V} will correspond on consecutive rising edges of the clock signal CLK to the data values D_{V3}, D_{V2}, D_{V1} and D_{V0}.

The write phase involves passing a current through the resistive elements 202, 203 of each of the non-volatile cells 204 to 207, via the transistor 216, in one direction or the other depending on the value of the data to be stored. The resistive elements 202, 203 of each non-volatile cell are orientated such that, for a given direction of current, they will be programmed to have opposite resistances.

As illustrated in FIG. 3, initially the write signals WRITE_3 to WRITE_0 are at a low state, such that none of the transistors 216 is conducting. The term “high state” is used herein to designate a voltage level close to or at the level of the supply voltage V_{DD}, while the term “low state” is used herein to designate a voltage level close to or at the ground voltage. The non-volatile cell 207 is for example programmed first by the data value Dv₃. Thus the write signal WRITE_3 for example goes high on a falling edge while the signal D_{V} has the value D_{V3}. At the same time, the control block 226 of FIG. 2 for example generates values of the control signals WN1, WP1, WN2 and WP2 to cause a current through the resistive elements 202, 203 of the non-volatile cell 207 in a given direction based on the data value D_{V3}. In particular, to generate a current in a direction from line 210 to line 214, the signals WP1 and WN1 are brought low, and the signals WP2 and WN2 are brought high. To generate a current in the opposite direction from line 214 to line 210, the signals WP1 and WN1 are brought high, and the signals WP2 and WN2 are brought low. The signal WRITE_3 stays high for a sufficient time to change the resistive states of the resistive elements 202, 203. For example, the write signals are asserted for a duration of between 0.1 ns and 20 ns. The signal D_{V} then transitions to the value D_{V2}, and the write signal WRITE_2 is asserted to cause the non-volatile cell 206 to be programmed, and so on and so forth, until all of the non-volatile cells 204 to 207 have been programmed.

In some embodiments, during the back-up operation, the multiplexer 110 is controlled to select the feedback line 108, such that, at the end of the back-up operation, the volatile cells 104 to 107 again store the data values D_{V0} to D_{V3} respectively.

FIG. 4 is a timing diagram showing an example of signals in the register 100 of FIG. 1 and in the non-volatile memory of FIG. 2 during a restoration operation. In particular, FIG. 4 shows examples of the clock signal CLK, the read signals READ_3 to READ_0 controlling the transistors 218 and 220 of the non-volatile memory cells 207 to 204 respectively, and the data signal D_{NV}.

As mentioned above, the restoration operation corresponds to an operation for transferring the data represented by the programmed resistive states of the resistive elements 202, 203 of the non-volatile cells 204 to 207 to the volatile cells 104 to 107. This involves transforming each data value from being represented by a programmed resistive state to being represented by voltage levels Q and Q̅ at the storage nodes 230, 232 of the read circuit 228.

During the back-up operation, the memory cells 104 to 107 are for example controlled by the selection signal SE to select the inputs S0 to S3 respectively to be propagated to their outputs.

The signal SENSE is for example initially low, such that NMOS transistor 230 of the read circuit 228 is non-conducting. Furthermore, the read signals READ_3 to READ_0 are for example all initially high, such that none of the PMOS transistors 218, 220 is conducting.

It is assumed in FIG. 4 that the bits D_{NV3} and D_{NV2} stored by non-volatile cells 207 and 206 are both at logic “0”, and that the bits D_{NV1} and D_{NV0} stored by non-volatile cells 205 and 204 are both at logic “1”.

The data value D_{NV3} stored by the non-volatile cell 204 is read first by bringing low the read signal READ_3, for example on the rising edge of the clock signal CLK, thereby activating the transistors 218 and 220. Thus currents are induced in the left-hand and right-hand branches of the non-volatile cell 207. At the same time, the signal SENSE for example goes high, activating the transistor 230 of the read circuit, and thereby equalizing to some extent the voltages Q and Q at the storage nodes 230, 232. Due to the difference in the programmed resistances of the resistive elements 202 and 203 of the non-volatile cell 207, the current in the left-hand branch is for example lower than the current in the right-hand branch, and this for example causes the voltage Q at storage node 230 to fall and settle at a level V₁ below a level of metastability M. The level of metastability M is a theoretical voltage level approximately halfway between the high and low voltage states, representing the level from which there would be equal probability of Q flipping to the high or low state. The signal SENSE is then brought low, turning off the transistor 230 of the read circuit, and the signal READ_3 is brought high, turning off the transistors 218 and 220 of the cell 207. The level of voltage Q thus goes to its closest stable state, which in the example of the data value D_{NV3} is the low state. However, it will be apparent to those skilled in the art that the level V₁ and the final stable state will depend on factors such as the ON resistances of the transistors 218, 220, 236 and 238.

The data value D_{NV3} is for example clocked by the first volatile cell 104 on the subsequent falling clock edge, labelled 402 in FIG. 4.

During the subsequent clock cycle, the data value D_{NV2} is read from the non-volatile cell 206 in a similar fashion, and this value is clocked by the volatile cell 104 on the subsequent falling clock edge 404. The data value D_{NV3} is also clocked by the volatile cell 105 on this clock edge.

The data value D_{NV1} is then read from the non-volatile cell 205, and in this case the data value is assumed to be at a logic “1”. When the signals READ_1 and SENSE are asserted low and high respectively, the voltage Q thus goes to a level V₂ slightly higher than the level of metastability M. When the signals READ_1 and SENSE then subsequently return to high and low states respectively, the voltage Q goes to its closed stable state, which is the high state. The data value D_{NV1} is clocked by the volatile cell 104 on the next falling clock edge 406, and the data values that were held by the cells 104 and 105 are clocked by the cells 105 and 106 respectively.

During the subsequent clock cycle, the data value D_{NV0} is read from the non-volatile cell 204 in a similar fashion, and this value is clocked by the volatile cell 104 on the subsequent falling clock edge 408. The data values that were held by the cells 104, 105 and 106 are clocked by the cells 105, 106 and 107 respectively, such that, at the end of the restoration operation, the cells 104 to 107 respectively store the values D_{NV0} to D_{NV3}.

FIG. 5 schematically illustrates the non-volatile memory 103 according to an example in which writing to the non-volatile cells 204 to 207 is performed in parallel. Therefore, rather than comprising a single write circuit 222 and a single write circuit 224, a pair of write circuits 222, 224 is coupled to each of the non-volatile memory cells 204 to 207. In particular, a corresponding write circuit 222 is coupled to the resistive element 202 of each non-volatile memory cell 204 to 207, and controlled by corresponding control signals WP1_n and WN1_n, with n equal to 0 to 3 for the cells 204 to 207 respectively. Similarly, a corresponding write circuit 224 is coupled to the resistive element 204 of each non-volatile memory cell 204 to 207, and controlled by corresponding control signals WP2_n and WN2_n, with n equal to 0 to 3 for the cells 204 to 207 respectively. The control circuit 226 of FIG. 2 is replaced in FIG. 5 by a control circuit 226 adapted to generate the sixteen control signals based on the data values D_{V0}, D_{V1}, D_{V2} and D_{V3}.

The common read circuit 228 is used for reading the data values D_{NV} stored by the non-volatile cells 204 to 207. However, the common line 210 at one input of the read circuit 228 is for example isolated from the resistive element 202 of each cell 204 to 207 by corresponding switches 502, and the common line 214 at the other input of the read circuit 228 is for example isolated from the resistive element 203 of each cell 204 to 207 by corresponding switches 502. The switches 502 are for example controlled by a write signal WRITE that remains high during the back-up operation such that the switches 502 are non-conducting.

FIG. 6 schematically illustrates the non-volatile memory 103 according to an example in which reading from the non-volatile cells 204 to 207 is performed in parallel. Therefore, rather than comprising a single read circuit 228, a corresponding read circuit 228 is coupled to each of the non-volatile memory cells 204 to 207. Furthermore, rather than being coupled to common lines 210 and 214, the outputs of the non-volatile memory cells 204 to 207 are for example coupled together via switches 602 so that they may be isolated from each other during the restoration operation.

The volatile portion 102 of the register 100 for example comprises multiplexers 604 to 607 having their outputs respectively coupled to the inputs D0 to D3 of the volatile cells 104 to 107. The multiplexers 604 to 607 receive at one of their inputs the data values D_{NV0}, D_{NV1}, D_{NV2} and D_{NV3} respectively, read by the read circuits 228 from the non-volatile cells 204 to 207. Another input of each multiplexer 604 to 607 receives the corresponding data signal D0 to D3. A selection signal S to each multiplexer 604 to 607 controls which input line selected, and is for example controlled during the restoration operation to select the data values D_{NV0}, D_{NV1}, D_{NV2} and D_{NV3} read from the non-volatile memory 103.

FIGS. 7A and 7B illustrate the structures of the resistive elements 202, 203 according to examples in which they are resistive spin transfer torque (STT) elements.

FIG. 7A illustrates an STT resistive element 700 with in-plane magnetic anisotropy. The element 700 is for example substantially cylindrical, but has a cross-section which is non-circular, for example oval, which leads for example to an increase in the retention stability of the resistive states when the device is programmed. The element 700 comprises bottom and top electrodes 702 and 704, each being substantially disc-shaped, and sandwiching a number of intermediate layers between them. The intermediate layers comprise, from bottom to top, a pinned layer 706, an oxidation barrier 708, and a storage layer 710.

The oxidation barrier 708 is for example formed of MgO or AlₓO_{y}. The pinned layer 706 and storage layer 710 are for example ferromagnetic materials, such as CoFe. The spin direction in the pinned layer 706 is fixed, as represented by an arrow from left to right in FIG. 7A. Of course, in alternative embodiments the spin direction could be from right to left in the pinned layer 706. However, the spin direction in the storage layer 710 can be changed, as represented by arrows in opposing directions in FIG. 7A. The spin direction is programmed by the direction of the write current I passed through the element, such that the spin direction in the storage layer is parallel, in other words in the same direction, or anti-parallel, in other words in the opposite direction, to that of the pinned layer 706.

FIG. 7B illustrates an STT resistive element 720 with perpendicular-to-plane magnetic anisotropy. Such a resistive element can for example be programmed by a lower write current I than the element 700 for a given size and/or for a given storage layer volume. Element 720 is substantially cylindrical, and for example has a cross-section which is circular. The element 720 comprises bottom and top electrodes 722 and 724, each being substantially disc-shaped and sandwiching a number of intermediate layers. The intermediate layers comprise, from bottom to top, a pinned layer 726, an oxidation barrier 728, and a storage layer 730. These layers are similar to the corresponding layers 706, 708 and 710 of element 700, except that the pinned layer 726 and storage layer 730 have perpendicular-to-plane anisotropy, as represented by the vertical arrows in layers 726 and 730 of FIG. 7B. The pinned layer 726 is illustrated as having a spin direction from bottom to top in FIG. 7B, but of course, in alternative embodiments, this spin direction could be from top to bottom.

An advantage of the embodiments described herein is that, by providing a register in which data is supplied serially to and/or from a non-volatile memory of the register, the data stored by the register can be backed-up and/or restored with relatively low energy consumption and while maintaining a relatively compact circuit.

Having thus described at least one illustrative embodiment, various alterations, modifications and improvements will readily occur to those skilled in the art.

For example, while examples have been described in which each non-volatile memory cell comprises a pair of resistive elements, it will be apparent to those skilled in the art that other circuit arrangements would be possible.

Furthermore, it will be apparent to those skilled in the art that the supply voltage VDD in the various embodiments could be at any level, for example between 1 and 3 V, and rather that being at 0 V, the ground voltage can also be considered as a supply voltage that could be at any level, such as a negative level.

Furthermore, it will be apparent to those skilled in the art that, in any of the embodiments described herein, all of the NMOS transistors could be replaced by PMOS transistors and/or all of the PMOS transistors could be replaced by NMOS transistors. It will be apparent to those skilled in the art how any of the circuits could be implemented using only PMOS or only NMOS transistors. Furthermore, while transistors based on MOS technology are described throughout, in alternative embodiments other transistor technologies could be used, such as bipolar technology.

Furthermore, it will be apparent to those skilled in the art that the various features described in relation to the various embodiments could be combined, in alternative embodiments, in any combination.

1. A register comprising:
a plurality of volatile memory cells each having a first input and an output, the volatile memory cells being coupled in series with each other via their first inputs and outputs;
a non-volatile memory comprising a plurality of non-volatile memory cells; and
one or more serial connections, wherein the non-volatile memory comprises either:
a common pair of write circuits for the plurality of non-volatile memory cells, and a read circuit associated with each of the non-volatile memory cells, each read circuit having its output coupled in parallel to a corresponding one of the volatile memory cells, the one or more serial connections being adapted to serially supply data to be written to the non-volatile memory from a last or another of the volatile memory cells to the non-volatile memory during a back-up operation of data stored by the volatile memory cells; or
a common read circuit for the plurality of non-volatile memory cells, and a pair of write circuits associated with each of the non-volatile memory cells, each write circuit being controlled based on a corresponding one of the outputs of the volatile memory cells to program a data value in the corresponding non-volatile memory cell, the one or more serial connections being adapted to serially supply data read from the non-volatile memory to a first of the volatile memory cells during a restoration operation of the data stored by the volatile memory cells.

2. The register of claim 1, wherein each of the volatile memory cells further comprises a second input for receiving data to be stored in the register, and a selection input for selecting one of the first and second inputs.

3. The register of claim 2, comprising a control block adapted to control the selection input of each of the volatile memory cells to select the first input during the restoration and/or back-up operation.

4. The register of claim 1, wherein the one or more serial connections is further adapted to input scan test data in series to the first of the volatile memory cells during a scan test operation.

5. The register of claim 1, further comprising a feedback line coupling the output of the last of the volatile memory cells to the first input of the first of the volatile memory cells.

6. The register of claim 1, wherein the outputs of the volatile memory cells are coupled in parallel to corresponding inputs of the non-volatile memory.

7. The register of claim 1, wherein the one or more serial connections are adapted to supply the data read from the non-volatile memory in series to the first of the volatile memory cells during the restoration operation or to supply the data to be written to the non-volatile memory in series from the last or another of the volatile memory cells to the non-volatile memory during a back-up operation.

8. The register of claim 1, wherein each of the plurality of non-volatile memory cells comprises:
first and second resistive elements, at least one of which is programmable to have one of at least two resistive states, a data value being represented by the relative resistances of the first and second resistive elements, the first resistive element being coupled between a first intermediate node and a first storage node of a read circuit and the second resistive element being coupled between a second intermediate node and a second storage node.

9. The register of claim 8, wherein at least one of said first and second resistive elements is one of:
a spin transfer torque element with in-plane anisotropy;
a spin transfer torque element with perpendicular-to-plane anisotropy;
a reduction oxide element;
a ferro-electric element; and
a phase change element.

10. A method of data back-up in the memory register of claim 1, comprising: serially supplying, by the one or more serial connections, data to be written to the non-volatile memory from the last or another of the volatile memory cells.

11. A method of restoring data in the memory register of claim 1, comprising: serially supplying, by the one or more serial connections, data read from the non-volatile memory to the first of the volatile memory cells.
